(19) United States
(12) Patent Application Publication
(10) Pub. No.: US 2025/0234470 A1
(43) Pub. Date: Jul. 17, 2025

(54) FLEXIBLE HYBRID ELECTRONICS ADAPTABLE FOR EXTREME ENVIRONMENTS

(71) Applicant: Purdue Research Foundation, West Lafayette, IN (US)

(72) Inventor: Muhammad Mustafa Hussain, West Lafayette, IN (US)

(21) Appl. No.: 19/018,365

(22) Filed: Jan. 13, 2025

Related U.S. Application Data
(60) Provisional application No. 63/620,420, filed on Jan. 12, 2024.

(51) Int. Cl. H05K 5/06

(52) U.S. Cl. CPC H05K 5/06

(57) ABSTRACT

Systems and methods to implement flexible hybrid electronics adaptable for extreme environments. One system includes an electronic system including at least one rigid electrical component. The electronic system may interact with an external environment having an environmental condition that satisfies an environment threshold that indicates whether the external environment is an extreme environment. The system may include an encapsulation material that encloses the electronic system. The encapsulation material may have a first material property that defines a bending radius of the encapsulation material such that the encapsulation material has a degree of flexibility that corresponds to the bending radius; and a second material property that establishes a compatibility of the encapsulation material with the external environment such that the encapsulation material prevents an adverse impact on the electronic system due to the external environment.

### CROSS-REFERENCE TO RELATED APPLICATIONS

This application claims priority to U.S. Provisional Application No. 63/620,420, filed Jan. 12, 2024, the entirety of which is incorporated herein by reference.

### STATEMENT REGARDING FEDERALLY SPONSORED RESEARCH

N/A

### BACKGROUND

Flexible and stretchable electronics are an emerging class of electronics, which can add value from the perspectives of, e.g., aesthetics, functionality, modularity, etc. Accordingly, the technology disclosed herein generally relates to flexible electronics.

The discussion above is merely provided for general background information and is not intended to be used as an aid in determining the scope of the claimed subject matter.

### SUMMARY

Various aspects of the present disclosure relate to flexible hybrid electronics, and, in particular, to flexible hybrid electronics that are adaptable for extreme environments.

According to one aspect of the present disclosure, a system is provided. The system may include an electronic system including at least one rigid electrical component. The electronic system may be configured to interact with an external environment. The external environment may have an environmental condition that satisfies an environment threshold. The environment threshold may indicate whether the external environment is an extreme environment. The system may include an encapsulation material that may be configured to enclose the electronic system. The encapsulation material may have a plurality of material properties. The plurality of material properties may include a first material property that may define a bending radius of the encapsulation material such that the encapsulation material may have a degree of flexibility that corresponds to the bending radius. The plurality of material properties may include a second material property that may establish a compatibility of the encapsulation material with the external environment such that the encapsulation material may prevent an adverse impact on the electronic system due to the external environment.

According to another aspect of the present disclosure, an assembly is provided. The assembly may include an electronic system. The electronic system may include a plurality of electrical components. The electronic system may be configured to be implemented within an external environment having an environmental condition that satisfies an extreme environment threshold. The assembly may include an encapsulation material that may be configured to enclose at least one electrical component of the plurality of electrical components. The encapsulation material may have a plurality of material properties. The plurality of material properties may include a first material property that may define a bending radius of the encapsulation material such that the encapsulation material may have a degree of flexibility that corresponds to the bending radius. The bending radius may be between approximately 1 centimeter and 2 centimeters. The plurality of material properties may include a second material property that establishes a compatibility of the encapsulation material with the external environment such that the encapsulation material prevents the environmental condition from having an adverse impact on the at least one electrical component of the electronic system.

According to another aspect of the present disclosure, an apparatus is provided. The apparatus may include an electronic system including a plurality of electrical components. The electronic system may be implemented within an external environment. The external environment may have an environmental condition that satisfies an environment threshold that classifies the external environment as an extreme environment. The environmental condition may include at least one of: a temperature that is within a temperature range defined by the environment threshold, the temperature range being-25 degrees Celsius to 130 degrees Celsius; a pressure that is within a pressure range defined by the environment threshold, the pressure range being 0 torr to 45600 torr; a humidity that is within a humidity range defined by the environment threshold, the humidity range being 20% to 100%; a salinity level that within of a salinity range defined by the environment threshold, the salinity range being 9 parts per thousand (ppt) to 36 ppt; or a pH within a pH range defined by the environment threshold, the pH range being 1 to 14. The apparatus may include an encapsulation material configured to enclose at least one electrical component of the plurality of electrical components. The encapsulation material may have a bending radius of approximately 1 centimeter and 2 centimeters. The encapsulation material may have a material property that is tolerant to the environmental condition of the external environment such that the encapsulation material prevents the environmental condition from having an adverse impact on the at least one electrical component of the electronic system.

### BRIEF DESCRIPTION OF THE DRAWINGS

The following drawings are provided to help illustrate various features of examples of the disclosure and are not intended to limit the scope of the disclosure or exclude alternative implementations.

FIG. 1 illustrates a system for implementing flexible hybrid electronics adaptable for extreme environments in accordance with various aspects of the present disclosure.

FIG. 2 is a table of example extreme environments.

FIG. 3 is a table of example environment thresholds in accordance with various aspects of the present disclosure.

FIG. 4 schematically illustrates an example electronic system in accordance with various aspects of the present disclosure.

FIG. 5 schematically illustrates an example configuration of the electronic assembly 105 in accordance with various aspects of the present disclosure.

FIGS. 6-17 illustrate an example generic process integration strategy for a heterogeneously integrated flexible 2.5/3D system in accordance with various aspects of the present disclosure.

FIG. 18 illustrates an example of flexible hybrid electronics with a fluidic assembly of chiplets in accordance with various aspects of the present disclosure.

FIG. 19 illustrates an example of flexible hybrid electronics with organic materials-based sensors in accordance with various aspects of the present disclosure.

FIG. 20 illustrates an example of flexible chiplets in accordance with various aspects of the present disclosure.

FIG. 21 illustrates an example flexible ADC development kit in accordance with various aspects of the present disclosure.

FIG. 22 illustrates an example flexible BLE development kit in accordance with various aspects of the present disclosure.

FIG. 23 illustrates an example flexible version of a microcontroller in accordance with various aspects of the present disclosure.

FIGS. 24A-24C illustrates examples of through via formation and gap fill with interconnects in accordance with various aspects of the present disclosure.

FIG. 25A is a graph illustrating a relationship between yield strength and applied stretch on a horseshoe in accordance with various aspects of the present disclosure.

FIG. 25B is a graph illustrating a relationship between total principal strain and applied stretch on a horseshoe in accordance with various aspects of the present disclosure.

FIG. 25C is a graph illustrating a relationship between yield strength and applied stretch on a spiral in accordance with various aspects of the present disclosure.

FIG. 25D is a graph illustrating a relationship between total principal strain and applied stretch on a spiral in accordance with various aspects of the present disclosure.

FIGS. 26A-26D illustrates a biofouling study on the encapsulated with a curated polymer in accordance with various aspects of the present disclosure.

FIG. 27 illustrates an example electronic assembly implemented on a crab in accordance with various aspects of the present disclosure.

FIG. 28 illustrates an example schematic of 2.5/3D flexible heterogeneously integrated system in accordance with various aspects of the present disclosure.

FIG. 29 illustrates a circuit block diagram of a common platform technology in accordance with various aspects of the present disclosure.

### DETAILED DESCRIPTION

The disclosed technology is not limited in its application to the details of construction and the arrangement of components set forth in the following description or illustrated in the following drawings. Other examples of the disclosed technology are possible and examples described and/or illustrated here are capable of being practiced or of being carried out in various ways. The terminology in this document is used for the purpose of description and should not be regarded as limiting. Words such as “including,” “comprising,” and “having” and variations thereof as used herein are meant to encompass the items listed thereafter, equivalents thereof, as well as additional items.

A plurality of hardware and software-based devices, as well as a plurality of different structural components can be used to implement the disclosed technology. In addition, examples of the disclosed technology can include hardware, software, and electronic components or modules that, for purposes of discussion, can be illustrated and described as if the majority of the components were implemented solely in hardware. However, in at least one example, the electronic based aspects of the disclosed technology can be implemented in software (for example, stored on non-transitory computer-readable medium) executable by one or more electronic processors. Although certain drawings illustrate hardware and software located within particular devices, these depictions are for illustrative purposes only. In some examples, the illustrated components can be combined or divided into separate software, firmware, hardware, or combinations thereof. As one example, instead of being located within and performed by a single electronic processor, logic and processing can be distributed among multiple electronic processors. Regardless of how they are combined or divided, hardware and software components can be located on the same computing device or can be distributed among different computing devices connected by one or more networks or other suitable communication links.

Flexible and stretchable electronics are an emerging class of electronics, which can add value from the perspectives of, e.g., aesthetics, functionality, modularity, etc. Although a variety of promising and exciting applications have been demonstrated within controlled lab environments, fully flexible electronic systems (e.g., where at least 90% of the components are fully, physically flexible) remains as an elusive goal. A majority of the flexible and stretchable electronics are being demonstrated based on the natural flexibility and stretching ability of materials, which may not have reached a maturity comparable to that of the existing state-of-the-art (SOTA) crystalline and physically rigid electronic materials. Therefore, a middle ground has been set as an effective merger of both the physically flexible components and the rigid integrated circuits (ICs) as flexible hybrid electronics. While that has accelerated demonstration of more innovative applications, the fullest potential of flexible and stretchable electronics still remains untapped.

As one example, the intracranial space of the brain is an uncertain environment area. Understanding brain mechanism, functionality, etc. can offer insight for treatment of many mental health related illnesses and challenges. As of today, a microneedle based neural array, The Utah Array™, is generally considered the gold standard. However, even with decade long success, within a limited time frame of about a year, such microneedle based neural arrays become unusable due to the physical protruding invasive contact with brain cells causing infections and pain. While Electroencephalography (EEG) and Electromyography (EMG) could have been a set of game changer technologies, readings of these technologies are generally not comprehensive enough to draw a decisively insightful conclusion from the data gathered by these technologies.

Therefore, a physically flexible brain mapping system, which can be in intimate contact with brain cells, placed in the intracranial space, and skull closed back, can be a real disruptive neural interface. To achieve this lofty goal, the components of such a system may have a high surface to volume ratio, be physically compliant and soft, or a combination thereof. Therefore, a physically, fully flexible electronic system, which is ultra-light-weight and potentially reversibly stretchable is a technological need. While such a goal may be attained robustly, deployment of such a system may often be in extreme and unusual environments (e.g., inside a human body, agricultural field, etc.). Typically, such environments are defined by the wide variation in environmental conditions, such as, e.g., temperature, pressure, vibration, gravitational acceleration, radiation exposure, humidity, pH, salinity, etc. In many of the defense, space, industrial and automobiles related applications such environments are common.

Due to the presence of a wide spectrum of determinant factors, the scope of an extreme and uncertain environment may be defined. By determining an environmental landscape, appropriate materials and processes may be selected for the development of the technology disclosed herein. For instance, the technology disclosed herein may include the development of a generic integration strategy to demonstrate a flexible hybrid electronic platform that, e.g., can be used for sensing and actuation (dual mode functionalities). In some instances, a hybrid set of materials that can withstand the target environmental conditions may be implemented via the technology disclosed herein. In some cases, such materials may be physically rigid. In some configurations, the materials may be ultra-scaled dimensional, physically compliant, or a combination thereof. Interconnections and packaging of the materials may be an effective solution for addressing space, weight, cost, or power consumption concerns. Therefore, in some configurations, the technology disclosed herein may identify a suitable set of materials and may demonstrate an industry compatible reliably manufacturable integration strategy that can deliver a “common platform technology/interface” suitable for a broad range of extreme environment applications.

Accordingly, as described in greater detail herein, the technology disclosed herein relates to flexible hybrid electronics that are adaptable for extreme environments.

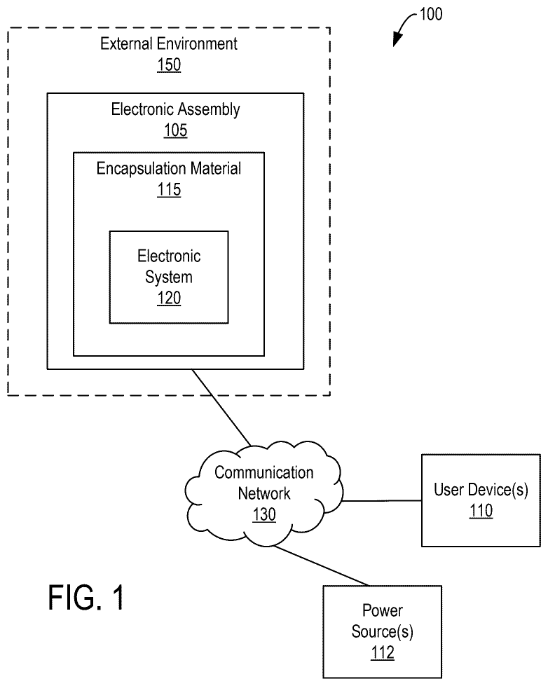

FIG. 1 illustrates a system 100 for implementing flexible hybrid electronics adaptable for extreme environments according to some examples. As illustrated in the example of FIG. 1, the system 100 can include an electronic assembly 105, one or more user device(s) 110, and one or more power source(s) 112. In some examples, the system 100 can include fewer, additional, or different components in different configurations than illustrated in FIG. 1. For example, as illustrated, the system 100 includes one electronic assembly 105, one user device 110, and one power source 112. However, in some examples, the system 100 can include fewer or additional electronic assemblies 105, user devices 110, power sources 112, or a combination thereof. As another example, components of the system 100 can be combined into a single device, divided among multiple devices, or a combination thereof.

The electronic assembly 105, the user device(s) 110, and the power source(s) 112 can communicate over wired or wireless communication networks 130. Portions of the communication networks 130 can be implemented using a wide area network, such as the Internet, a local area network, such as a Bluetooth™ network or Wi-Fi, and combinations or derivatives thereof. In some examples, the communication network 130 represents a direct wireless link between two components of the system 100 (e.g., via a Bluetooth™ or Wi-Fi link). Alternatively, or in addition, in some examples, two or more components of the system 100 can communicate through an intermediary device of the communication network 130 not illustrated in FIG. 1.

The user device 110 can include, e.g., a desktop computer, a laptop computer, a tablet computer, an all-in-one computer, a notebook computer, a terminal, a smart telephone, a smart television, a smart speaker, a smart imaging device, or another suitable computing device that interfaces with a user. A user may interact with the user device 110 in order to interact with the electronic assembly 105. As one example, the user may interact with the user device 110 to interact with (e.g., view, edit, etc.) data collected via the electronic assembly 105, as described in greater detail herein. As another example, the user may interact with the user device 110 to facilitate (or otherwise control) performance of an action or task via the electronic assembly 105, such as, e.g., while the electronic assembly 105 is deployed (or otherwise positioned) within an external environment (also referred to herein as an extreme environment), as described in greater detail herein. Although not illustrated in FIG. 1, the user device 110 may include similar components as described herein with respect to an electronic system of the electronic assembly 105, such as electronic processor (e.g., a microprocessor, an application-specific integrated circuit (ASIC), or another suitable electronic device), a memory (e.g., a non-transitory, computer-readable storage medium), a communication interface, such as a transceiver, for communicating over the communication network 130 and, optionally, one or more additional communication networks or connections, and one or more human machine interfaces (e.g., display devices or the like). In some configurations, the user device 110 includes additional, fewer, or different components than the electronic system of the electronic assembly 105.

As described in greater detail herein, the power source(s) 112 may be an external power source of the electronic assembly 105 that, when electrically coupled to the electronic assembly 105 (or the electronic system thereof), may provide power to the electronic assembly 105 (or the electronic system thereof). Accordingly, in some configurations, the power source(s) 112 may be utilized to charge a power storage device of the electronic system 120, as described in greater detail herein.

The electronic assembly 105 may be configured (or otherwise designed) to be implemented within a particular application or environment. For example, the electronic assembly 105 may be a monitoring, measuring, or controlling system to be implemented within an extreme or uncertain environment. For instance, as illustrated in FIG. 1, the electronic assembly 105 may be deployed (or otherwise positioned) within an external environment 150. The external environment 150 may be an extreme environment.

An extreme environment may be an environment (or habitat) that exhibits extreme or harsh environmental conditions, such that, e.g., survival or existence within that environment is particularly difficult or challenging. An environmental condition may be a characteristic or property of an environment, such as, e.g., a temperature, a pressure, a humidity, a wind speed, etc. For instance, in some cases, an extreme environment may include an environment in which a human (or other organism) could not survive in due to environmental condition(s) that may be detrimental or fatal to humans (or other organisms). Examples of extreme environmental conditions may include, e.g., extremely hot or cold temperatures, high pressures, extremely acidic (pH<5) or alkaline (pH>9), high salt concentrations, high-radiation, etc. Examples of extreme environments may include, e.g., high-radiation environments, high pressure environments, high pressure environments, extremely acidic or alkaline environments, hypersaline environments, a biological environment internal to a living or nonliving being (e.g., a human, an animal, or other organism), a geothermal environment, an outer space environment (e.g., at or beyond least 100 kilometers from Earth's surface); an arctic environment, a tropical environment, etc. As a specific example, the Sahara dessert may be considered an extreme environment due to the lack of precipitation and high temperatures of the Sahara desert (e.g., 50 degrees Celsius). As another specific example, Antarctica may be considered an extreme environment due to the severely low temperatures. For instance, in some configurations, the electronic assembly 105 may be deployed (or implemented) in applications associated with extreme environments, such as, e.g., space exploration, automotive industries, downhole oil and gas industries, oceanic environments, geothermal power plants, within a brain cavity of a human, etc.

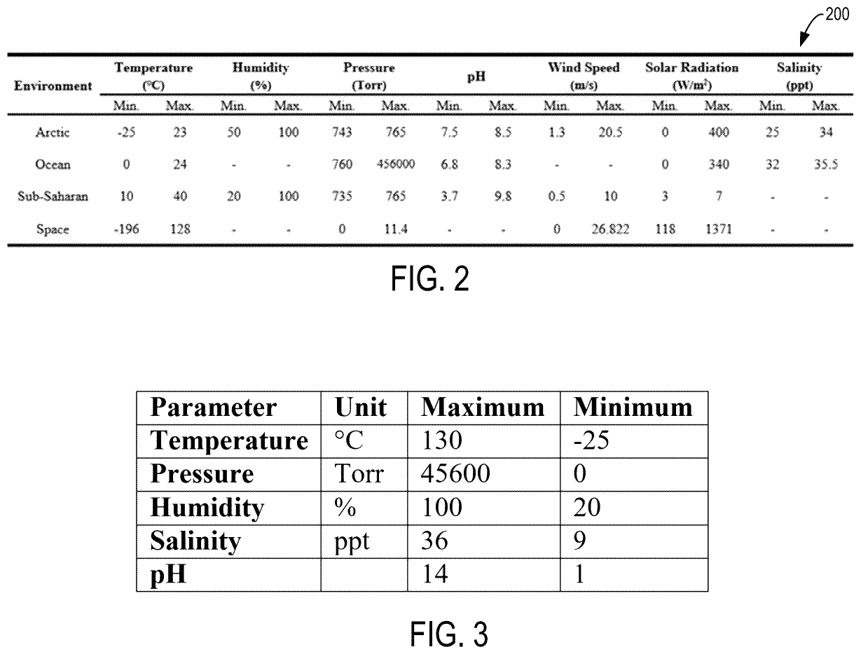

For example, FIG. 2 is a table 200 of example environmental conditions of extreme environments. In the example of FIG. 2, the extreme environments include an arctic environment, an ocean environment, a sub-Saharan environment, and a space environment. As illustrated in FIG. 2, each environment is associated with one or more environmental ranges of environmental conditions (e.g., a maximum condition and a minimum condition). For instance, the table 200 includes a minimum temperature, a maximum temperature, a minimum humidity, a maximum humidity, a minimum pressure, a maximum pressure, a minimum pH, a maximum pH, a minimum wind speed, a maximum wind speed, a minimum solar radiation, a maximum radiation, a minimum salinity, and a maximum salinity. In some instances, an environment may be considered an extreme environment when the environment has an environmental condition that may range between a minimum condition and a maximum condition, where such range between the minimum condition and the maximum condition spans a broad range of metrics or values. In some instances, these minimum and maximum conditions may be abnormal or severe environmental conditions.

In some instances, the external environment 150 may be classified (or otherwise determined) as an extreme external environment when an environmental condition of the external environment 150 satisfies a criterion or threshold indicative of abnormal or sever environmental conditions (also referred to herein as an environment threshold or an extreme environment threhsold). For example, the environment threhsold may indicate whether a corresponding external environment is an extreme environment. For example, with reference to the table 200 of FIG. 2, the external environment 150 may be considered an extreme environment when the external environment 150 has an environmental condition that may fall between a minimum condition and a maximum condition that are abnormal or severe (e.g., within an environmental range of a corresponding environmental condition that includes a broad range of metrics or values).

FIG. 3 illustrates a table 300 of example environment thresholds according to some configurations. As illustrated in FIG. 3, the table 300 includes five example parameters (or environmental conditions) (e.g., temperature pressure, humidity, salinity, and pH). The table 300 also indicates a respective environmental threshold (or range) for each environmental condition (e.g., a minimum condition and a maximum condition). In some configurations, the technology disclosed herein may be configured to tolerate (or otherwise be compatible with) environmental conditions within a respective environmental threshold (or range), including a corresponding minimum condition and a corresponding maximum condition. For example, the electronic assembly 105 may be configured to tolerate (or be compatible with) any environmental condition within a respective environmental threhsold (or range) (e.g., tolerant to a minimum condition as well as a maximum condition).

As one example, the environment threshold may define (or otherwise establish) a temperature range. The temperature range may be an ambient temperature range. The temperature range may be associated with a first endpoint (a minimum temperature) and a second endpoint (a maximum temperature). While some temperatures within the temperature range may be considered “normal” (or not extreme) (e.g., temperatures within a middle portion of the temperature range), other temperatures included in the temperature range may be considered “abnormal” (or extreme) (e.g., temperatures proximate or near a minimum or maximum temperature of the temperature range). As one specific example, with reference to FIG. 3, the environment threshold may define a temperature range that substantially includes −25 degrees Celsius as a first endpoint and 130 degrees Celsius as a second end point (e.g., the environment threshold is a temperature range of-25 degrees Celsius to 130 degrees Celsius). Following this example, when the external environment 150 may have a temperature (e.g., an environmental condition) that can range between −25 degrees Celsius and 130 degrees Celsius (e.g., be any value within the temperature range of-25 degrees Celsius to 130 degrees Celsius), the external environment 150 may be considered an extreme environment.

Alternatively, or in addition, in some examples, the environment threshold may define a pressure range. In some examples, with reference to FIG. 3, the pressure range may substantially include 0 torr as a first endpoint and 45600 torr as a second endpoint (e.g., the environment threshold is a pressure range of 0 torr to 45600 torr). Following this example, when the external environment 150 may have a pressure (e.g., an environmental condition) that can range between 0 torr to 45600 torr (e.g., can be any value within the pressure range of 0 torr to 45600 torr), the external environment 150 may be considered an extreme environment.

Alternatively, or in addition, in some examples, the environment threshold may define a humidity range. In some examples, with reference to FIG. 3, the pressure range may substantially include 20% as a first endpoint and 100% as a second endpoint (e.g., the environment threshold is a humidity range of 20% to 100%). Following this example, when the external environment 150 may have a humidity (e.g., an environmental condition) that can range between 20% to 100% (e.g., be any value within the humidity range of 20% to 100%), the external environment 150 may be considered an extreme environment.

Alternatively, or in addition, in some examples, the environment threhsold may define a salinity range. In some examples, with reference to FIG. 3, the salinity range may substantially include 9 parts per thousand (ppt) as a first endpoint and 36 ppt as a second endpoint (e.g., the environment threshold is a salinity range of 9 ppt to 36 ppt). Following this example, when the external environment 150 may have a salinity level (e.g., an environmental condition) that can range between 9 ppt to 36 ppt (e.g., be any value within the salinity range of 9 ppt to 36 ppt, the external environment 150 may be considered an extreme environment.

Alternatively, or in addition, in some examples, the environment threhsold may define a pH range. In some examples, with reference to FIG. 3, the pH range may substantially include 1 as a first endpoint and 14 as a second endpoint (e.g., the environment threshold is a pH range of 1 to 14). Following this example, when the external environment 150 may have a pH (e.g., an environmental condition) that can range between 1 to 14 (e.g., be any value within the pressure range of 1 to 14), the external environment 150 may be considered an extreme environment.

Returning to FIG. 1, the electronic assembly 105 may include an encapsulation material 115 and an electronic system 120. In some examples, the system 100 (or components thereof) can include fewer, additional, or different components in different configurations than illustrated in FIG. 1.

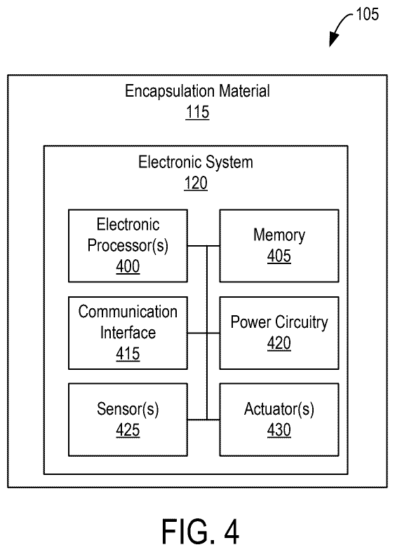

The electronic system 120 may include one or more electrical components. In some instances, the electrical component(s) may be rigid. For instance, in some configurations, the electronic system 120 may include one or more physically rigid electrical components. For example, FIG. 4 illustrates an example of the electronic system 120 according to some configurations. As illustrated in FIG. 4, the electronic system 120 may include one or more electronic processors 400, a memory 405, a communication interface 415, power circuitry 420, one or more sensor(s) 425, and one or more actuator(s) 430. In some examples, the system 100 (or components thereof) can include fewer, additional, or different components in different configurations than illustrated in FIG. 4. The electronic system 120 can perform additional functionality other than the functionality described herein. Also, the functionality (or a portion thereof) described herein as being performed by the electronic system 120 can be performed by another component, distributed among multiple components, combined with another component, or a combination thereof. A rigid electrical component may be one that is not generally flexible, having a larger bending radius approximately or above, for example, 100 times the thickness of the component.

The communication interface 415 can include a transceiver that communicates with the user device(s) 110, the power source(s) 112, another device of the system 100, another device external or remote to the system 100, or a combination thereof over the communication network 130 and, optionally, at least one other communication network or connection. The electronic processor 400 may include a microprocessor, an ASIC, or another suitable electronic device for processing data (e.g., a microcontroller or the like), and the memory 405 may include a non-transitory, computer-readable storage medium. The electronic processor 400 is configured to retrieve instructions and data from the memory 405 and execute the instructions.

For example, the memory 405 may include a control program or instructions that, when executed by the electronic processor 400, control functionality of the electronic assembly 105 (or component(s) thereof). As described herein, the electronic system 120 may be implemented to interact (or otherwise interface) with the external environment 150 (or an object or component included therein). Accordingly, the electronic processor 400 may control how the electronic system 120 interacts (or interfaces) with the external environment 150 (or an object or component included therein). As one example, the electronic processor 400 may monitor a parameter of the external environment 150 (or object(s) therein) using the sensor(s) 425, as described in greater detail herein. As another example, the electronic processor 400 may control the actuator(s) 430 to perform an action with respect to an element (or object) included in the external environment 150. As one specific example, when the electronic assembly 105 is deployed within a human body, the electronic processor 400 may control the actuator(s) 430 to provide a medication, such as, e.g., in response to detecting a particular parameter with the sensor(s) 425.

The power circuitry 420 may be configured to provide power to one or more components of the electronic system 120, such as, e.g., the electronic processor 400, the actuator(s) 430, the sensor(s) 425, etc. In some configurations, the power circuitry 420 may include one or more components configured to manage the distribution of power within the electronic system 120. In some configurations, the power circuitry 420 may include a power storage device, such as, e.g., a capacitor, a battery (e.g., a lithium-ion battery, etc.), another type of power storage device, etc. In some instances, the power circuitry 420 may receive power from the power source(s) 112 via the communication interface 415 (e.g., via an electrical connection between the communication interface 415 and the power source(s) 112, such as, e.g., a cable, a wire, etc.). Accordingly, in some configurations, the communication interface 415 may be a power port or interface configured to receive power from an external power source (e.g., the power source 112).

The actuator(s) 430 may include, e.g., a motor, a cylinder, a valve, etc. The actuator(s) 430 may be of various types, such as, e.g., pneumatic, hydraulic, electric, magnetic, thermal, mechanical, etc. The actuator(s) 430 may interact (or interface) with the external environment 150 (or an object or element included therein) responsive to control signals from the electronic processor 400. In some examples, the actuator(s) 430 interact (or interface) with the external environment 150 (or object or element included therein) by performing an action or task with respect to the external environment 150, as described in greater detail herein. For example, such an action or task may include outputting an electrical signal or pulse, dispensing a fluid or other substance (e.g., a medication), palpating an object included in the external environment 150 (e.g., an internal organ of a human being), etc.

The sensor(s) 425 may be configured to collect data (sensor data) related to the external environment 150, as described in greater detail herein. In some cases, the sensor(s) 425 may collect data describing the external environment 150 (or an environment condition thereof). Alternatively, or in addition, the sensor(s) 425 may collect data describing an object or element included within the external environment 150. Such an object or element may include, e.g., an organism (e.g., an internal organ or portion of a human, an animal, a plant, etc.), a substance within the external environment 150 (e.g., oil, gas, soil, etc.), etc. The sensor(s) 425 may include various types of sensors, such as, e.g., a pressure sensor, a humidity sensor, an image sensor, a microphone, a temperature sensor, a radiation sensor, a salinity sensor, a wind speed sensor, a pH sensor, etc.

The electronic system 120 (or component(s) thereof) may be included within (or otherwise enclosed by) the encapsulation material 115. In some configurations, each component of the electronic system 120 is enclosed by the encapsulation material 115 such that, when the electronic assembly 105 is implemented (or otherwise positioned) within the external environment 150, none of the components of the electronic system 120 are directly exposed to the external environment 150. Alternatively, in some configurations, a portion of the electronic system 120 (or component(s) thereof) are partially enclosed by the encapsulation material 115. For instance, in some examples, at least one component (or a portion thereof) of the electronic system 120 is not enclosed by the encapsulation material 115 such that, when the electronic assembly 105 is implemented (or otherwise positioned) within the external environment 150, that at least one component (or a portion thereof) is directly exposed to the external environment 150. In such instances, the at least one component (or a portion thereof) may be specifically configured to withstand (or tolerate) the external environment 150. For example, in some configurations, at least one component (or a portion thereof) of the electronic system 120 may be compatible with the external environment 150 such that the external environment 150 (or extreme environment condition thereof) does not adversely impact (e.g., damage, compromise, etc.) that at least one component (or a portion thereof).

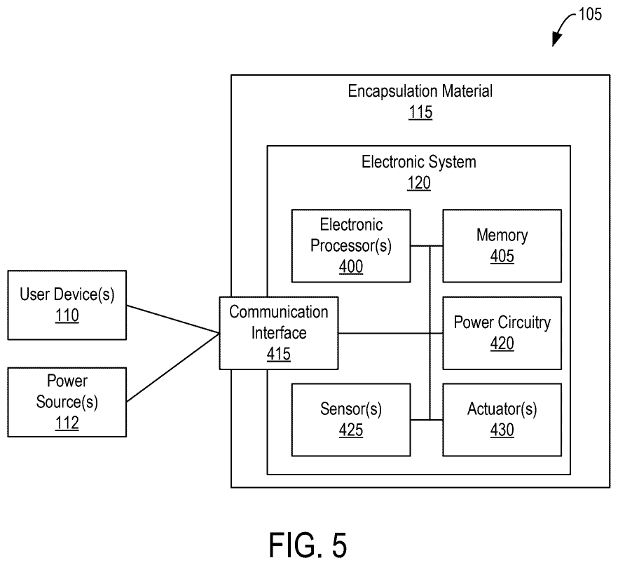

For example, FIG. 5 illustrates an example configuration of the electronic assembly 105 where the communication interface 415 (or a portion thereof) is not enclosed by the encapsulation material 115, and, as such, the communication interface 415 (or a portion thereof) may be exposed to the external environment 150 (or an extreme environment condition thereof). In some cases, the communication interface 415 may be exposed such that one or more electrical or communication couplings may be made, such as, e.g., to the user device(s) 110, the power source(s) 112, etc. (as illustrated in FIG. 5). For example, the electronic system 120 may be coupled with the user device(s) 110 via the communication interface 415 to facilitate outputting data collected by the electronic system 120 (using the sensor(s) 425) to the user device(s) 110. As another example, the electronic system 120 may be coupled with the power source(s) 112 via the communication interface 415 to facilitate power transfer to the electronic system 120 (e.g., charging). As another example, the electronic system 120 may be coupled with the user device(s) 110 via the communication interface 415 to facilitate the transfer of control instruction(s) or program(s) to the electronic system 120 from the user device(s) 110.

The encapsulation material 115 may be configured to enclose the electronic system 120 (or component(s) thereof). In some configurations, the encapsulation material 115 may be glass, such as, e.g., a flexible glass.

The encapsulation material 115 may be implemented in order to protect (e.g., mitigate or prevent) the electronic system 120 (or a portion thereof) from being damaged or compromised as a result of being exposed to the extreme environment (or environmental condition thereof). For instance, the encapsulation material 115 may shield the electronic system 120 (or component(s) thereof) from a potential adverse impact that exposure to the extreme environment may cause. For example, when the electronic system 120 (or component(s) thereof) is exposed to an extreme environment (or environmental condition thereof) without being enclosed by the encapsulation material 115, the environmental condition may have an adverse impact on the electronic system 120 (or a component thereof). However, when the electronic system 120 (or component(s) thereof) is enclosed by the encapsulation material 115 prior to deployment (or exposure) to the extreme environment, the encapsulation material 115 may mitigate or prevent an adverse impact.

Alternatively, or in addition, the encapsulation material 115 may be implemented in order to provide flexibility (e.g., a degree of flexibility) with respect to the electronic system 120 (or component(s) thereof). For example, while the electrical system 120 may include one or more physically rigid components, by enclosing the physically rigid components of the electrical system 120 with a flexible material (e.g., the encapsulation material 115), a degree of flexibility may be introduced to the electronic assembly 105. Accordingly, in some examples, the encapsulation material 115 has a bending radius such that the encapsulation material 115 may be flexible (e.g., a degree of flexibility that corresponds to the bending radius), and, ultimately, such that the electronic assembly 105 may be flexible.

A bending radius generally represents the smallest radius at which a material can be bent without damage, kinking, or shortening a lifespan of the material. The smaller the bending radius, the more flexible the material. In some configurations, the bending radius of the encapsulation material 115 may be approximately 1 centimeter to 2 centimeters. For example, in some instances, the bending radius may be substantially equal to 1 centimeter. As another example, in some instances, the bending radius of the encapsulation material 115 may be substantially equal to 2 centimeters. As yet another example, in some instances, the bending radius of the encapsulation material 115 may be substantially equal to a value between 1 centimeter and 2 centimeters. As such, in some examples, the bending radius of the encapsulation material 115 may be substantially greater than or equal to 1 centimeter and less than or equal to 2 centimeters. In some instances, the bending radius of the encapsulation material 115 may be a value other than 1 centimeter, 2 centimeters, or a value between 1 to 2 centimeters. As one example, the bending radius of the encapsulation material 115 may be substantially equal to 0.5 centimeters. As another example, the bending radius of the encapsulation material 115 may be substantially equal to 2.5 centimeters. As another example, the bending radius of the encapsulation material 115 may be less than 2.5 centimeters, less than 2 centimeters, less than 1.5 centimeters, or less than 1 centimeter. Accordingly, in some configurations, the bending radius of the encapsulation material 115 may be specifically tailored (or custom) to a particular application (e.g., an intended application) of the electronic assembly 105.

As one specific example, the encapsulation material 115 may be configured for approximately 30,000 bending cycles, a bending duration of approximately three continuous months, a bending radius 0.5 cm, or a combination thereof.

Accordingly, in some configurations, the encapsulation material 115 may include one or more material properties, such as, e.g., a material property defining a bending radius of the encapsulation material 115, a material property defining a compatibility (or tolerance) of the encapsulation material 15 with respect to the external environment 150 (or extreme environment condition thereof), etc.

In some configurations, the technology disclosed herein may implement (or otherwise facilitate) a generic process integration strategy. A generic process integration strategy may be a reliable and robust sequence of microfabrication processes which can maximize yield of an intended device or system with the desired functionalities, performances and reliability. As one example, semiconductor industries have used a self-aligned gate first integration strategy to fabricate uncounted numbers of transistors with 80% or more yield. Such an integration strategy may include source/drain activation anneal being carried out after defining the final gate stack, which may be thermally stable (even after the aforementioned annealing process induced thermal budget). A generic process integration strategy may establish baseline processes, which can be altered and tested time to time for developing new processes, optimizing processes, exploring new materials, narrowing down options, rapid prototyping, and, eventually, ultra-high-volume manufacturing. At some point, such strategies become pre-competitive and therefore the alteration and evolution of such strategies also become less resource exhaustive. The technology disclosed herein may define and demonstrate a reliable and robust process integration strategy for flexible hybrid electronics for extreme environments that may be laterally transferable to mainstream electronics manufacturing facilities for high volume production.

In some configurations, the technology disclosed herein may implement (or otherwise include) a common platform technology. One example of a common platform technology may include, e.g., Raspeberry Pi, which is a set of miniaturized computers. The technology disclosed herein may demonstrate a standalone common platform technology with multi-functionality to prove the efficacy of the generic process integration strategy. Functionality of the technology disclosed here may include, e.g., temperature, pressure, pH, and salinity sensing. In some examples, the technology disclosed herein may be used in both underwater and outside of the water applications. In some further examples, the technology disclosed herein may have a vast range of relevant applications, such as, e.g., defense applications (e.g., U.S. Navy, U.S. Marine Corps., U.S. Army, U.S. Space Force, U.S. Air Force, etc.), space exploration and applications (e.g., NASA, SpaceX, etc.), petrochemical industries, fisheries, electric vehicles, oceanic exploration and applications (e.g., oceanic resources, conservation of marine life, extraction of minerals, etc.), natural resource extraction and applications (e.g., geothermal power plants, mining, oil and gas industries, etc.), etc.

The technology disclosed herein proposes a solution that may be based on a set of generic process integration sequences related to a fully physically conformal common platform technology (e.g., a platform for interfacing with sensors and actuators), which are extreme environment compatible. The technology disclosed herein is described with reference to high temperature, thermal cycle, arctic environment, humidity, salinity and pH variation as identifiers of extreme environments. However, the technology disclosed herein may alternatively or additionally applicable to other identifiers of extreme environments. While the technology disclosed herein is described with respect to a flexible glass being the encapsulation material 115, other materials may be implemented or applicable to the technology disclosed herein. For example, in addition to flexible glass as a potential packaging material (e.g., the encapsulation material 115), copper, aluminum, graphene as an interconnect material and heat spreader, low and high-k material, the technology disclosed herein may be implemented or otherwise use off-the-shelf chiplets and transform the off-the-shelf chiplets into flexible chiplets. These chiplets may also be extreme environment compatible. Therefore, we investigate gallium nitride, gallium arsenide, silicon carbide and diamond (stretched goal) based devices and chiplets in addition to their silicon and silicon-on-insulator counterparts.

To define a generic process integration strategy, the technology disclosed herein may be implemented or otherwise use off-the-shelf bare die chiplets, such as, e.g., microcontrollers (e.g., the electronic processor(s) 400), a Bluetooth (BLE) chip (e.g., the communication interface 410), a sensory chip (e.g., the sensor(s) 425), and a battery (e.g., the power circuitry 420). As host substrates, the technology disclosed herein may explore flexible glass and ceramics, which may also be investigated as potential packaging materials (e.g., the encapsulation material 115). Flexible glass and ceramics may be geometrically configured and patterned to be reversibly stretchable. In some configurations, the technology disclosed herein may include deployment of state-of-the-art complementary metal oxide semiconductor (CMOS) based processes for rapid transfer to technology. The technology disclosed herein may investigate copper, aluminum, and graphene as a potentially highly thermally conductive heat spreader and highly conductive interconnect material. The technology disclosed herein may investigate a broad range of dielectric materials (both low and high k), which may be extreme environment compatible as well as cost effective. The technology disclosed herein may explore sustainable materials as sensory and actuating materials.

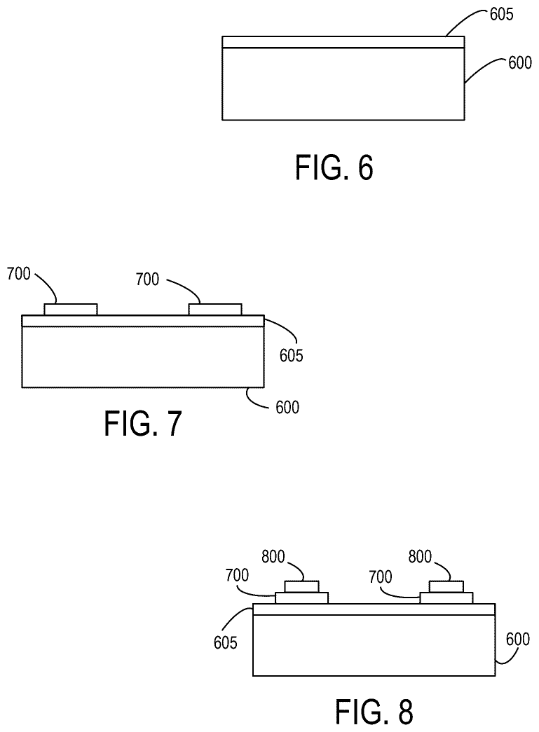

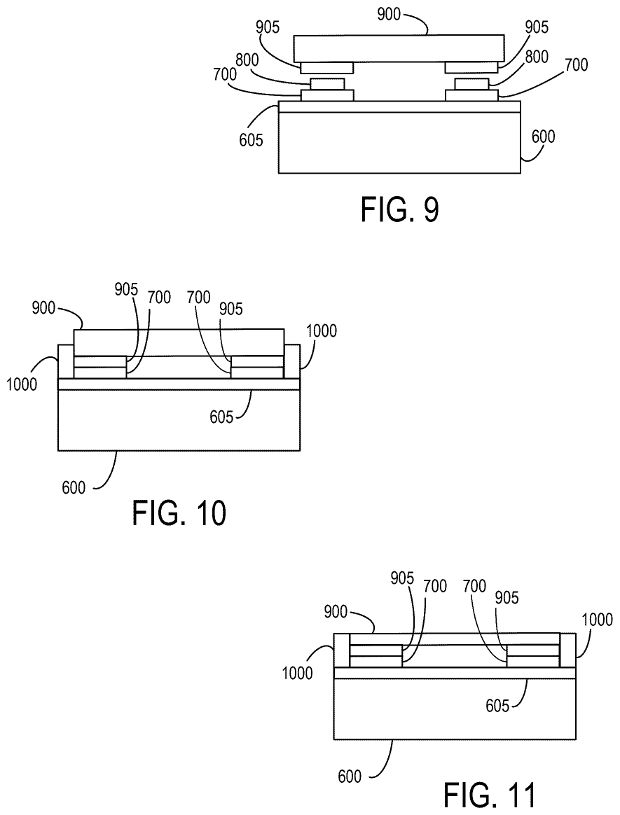

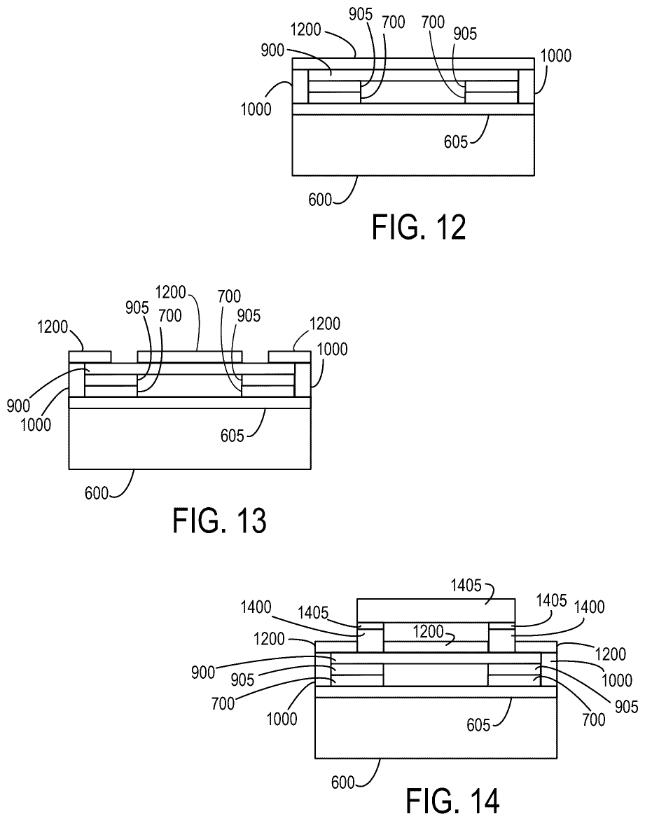

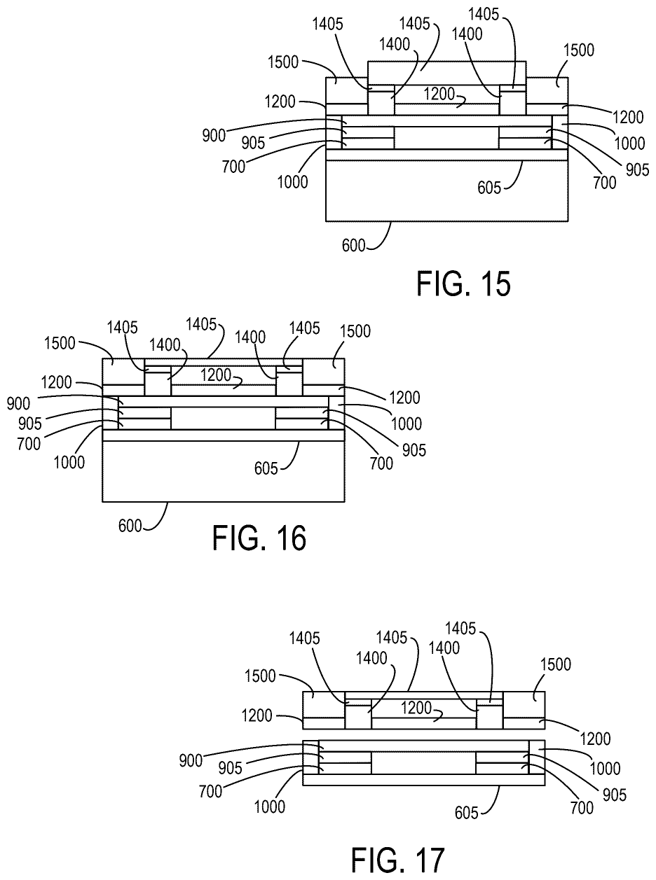

FIGS. 6-17 schematically illustrate an example generic process integration strategy for a heterogeneously integrated flexible 2.5/3D system according to some configurations described herein. FIG. 6 illustrates an example flexible glass substrate 600, which includes a top portion 605. FIG. 7 illustrates deposition and patterning of a first layer of metal (M1) 700 on the substrate (e.g., the flexible glass substrate 600). FIG. 8 illustrates the addition of solder balls or silver paste 800. FIG. 9 illustrates the addition of a chip component 900 (e.g., an integrated circuit (IC)), having a layer of metal 905. FIG. 10 illustrates the chip component 900 being bonded and packaged with thermally and mechanically compatible filler material package 1000, whose viscosity and phase can be appropriately controlled. FIG. 11 illustrates back etch flexing with respect to the chip component 900. FIG. 12 illustrates the addition of a second filler material layer 1200. FIG. 13 illustrates vias of the second filler material layer 1200 into three parts. FIG. 14 illustrates the addition of a second metal layer 1400 and the addition of a second chip component 1405 (e.g., an IC). FIG. 15 illustrates the addition of a second filler material package 1500. FIG. 16 illustrates the back etching with respect to the second chip component 1405. FIG. 17 illustrates thinning down the flexible glass substrate 600, such that only the top portion 605 remains.

In some instances, a hybrid set of materials may be implemented for an effective solution for extreme environment applications. As such, in some cases, the technology disclosed herein may implement a 2.5/3D-IC architecture and associated integration strategy (e.g., as described herein with respect to FIGS. 6-17). As noted herein, the range and applications spectrum of extreme environment electronics are far larger to be confined with a limited number of tests and demonstrations. Therefore, various sets of materials and relevant processes may be implemented.

As one example, the technology disclosed herein may be implemented using off-the-shelf bare die chiplets. Commercially available bare die chiplets may be based on a broad variety of materials, such as, e.g., Silicon (Si), Silicon-on-Insulator (SOI), Gallium Arsenide (GaAs), Indium Gallium Arsenide (InGaAs), Gallium Nitride (GaN), Silicon Carbide (SIC), etc. The technology disclosed herein allows for implementation of a generic process integration sequence that can integrate off-the-shelf bare die chiplets seamlessly. The technology disclosed herein may optimize compatibility, selectivity, etch potential, and effectiveness of such chiplets and, in some instances, with a variety of microfabrication processes, which may include through via formation (e.g., similar to through silicon via). In some instances, the technology disclosed herein may determine and prescribe the most optimal process(es) for through other materials (such as, e.g., GaN, GaAs, InGaAs, SiC, etc.) via and via filling using electroplating or Electrochemical Deposition (ECD) method(s).

As another example, the technology disclosed herein may be implemented using host substrate and encapsulation materials (e.g., the encapsulation material 115, as described herein). Although flexible printed circuit boards (PCBs) can endure temperature as high as 400° C., due to the thin nature of PCBs, thinned bare die chiplets cannot be embedded within PCBs. Therefore, in some configurations, the technology disclosed herein may be implemented using flexible glass and ceramic materials. Such materials may be highly promising materials to serve as alternative PCB materials when appropriately functionalized or coated and patterned. Therefore, the technology disclosed herein may involve deposition/dispensing/R2R printing of interconnect layers, laser, ion milling, etching, etc. based patterning and grooving of the host substrates. The technology disclosed herein may involve developing and optimizing low-cost but effective and manufacturable additive (e.g., using 3D printing) and subtractive processes for rapid integration into mainstream electronics manufacturing plants and lines.

As another example, the technology disclosed herein may implement copper, carbon nanotube, or graphene as potential interconnect materials. Since copper is an industry standard interconnect material, explorations of carbon nanotube and graphene may provide extended insight regarding potential utilization as interconnect materials and actual integration strategy for industry standard manufacturing. In some instances, the technology disclosed herein may use a laser induced graphene growth, a low cost growth process for carbon nanotubes, and a directed assembly using robotics based dispensing or roll-to-roll (R2R) printing on flexible glass and ceramics as well as inside tightly dense interlayer dielectric cavities and grooves.

As another example, the technology disclosed herein may use spin-on-dielectric as well as spin-on-glass as interlayer dielectric. The efficacy of such interlayer dielectrics with industry standard silicon dioxide and its different variations may be compared. In some instances, certain polymeric materials may be implemented depending on sustainability and longevity of such polymeric materials within the targeted extreme environmental conditions. For underwater and outside of water, the common platform technologies may vary in their material integration.

As another example, the technology disclosed herein may implement one or more thermal management components. In some instances, a separate heat sink may not be integrated in the microsystems described herein. Therefore, in some examples, the technology disclosed herein may implement naturally highly thermally conductive material, such as, e.g., graphene. In some instances, a host substrate and packaging materials may be electrically insulating and thermally conductive. In some instances, an emerging wide band gap material, such as, e.g., Aluminum Nitride (AlNx) may show higher thermal conductivity but lower electrical conductivity. In some instances, the technology disclosed herein may be implemented with such materials as a thermal management material. We look forward to exploring such materials as a potential thermal management material.

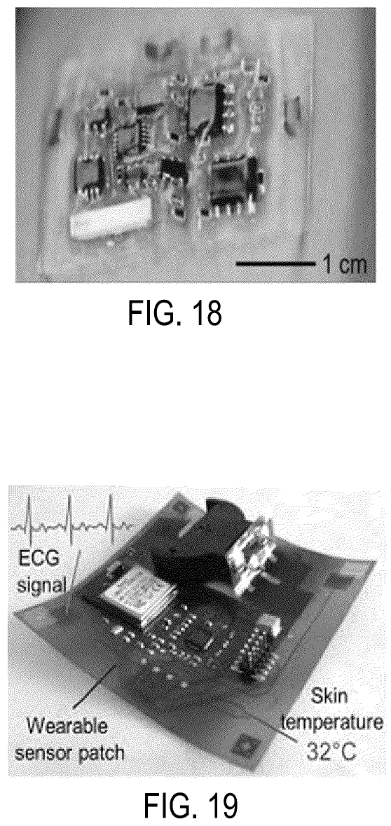

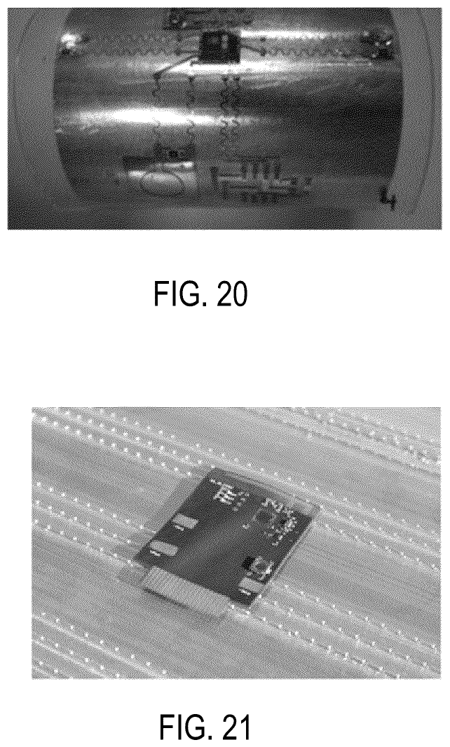

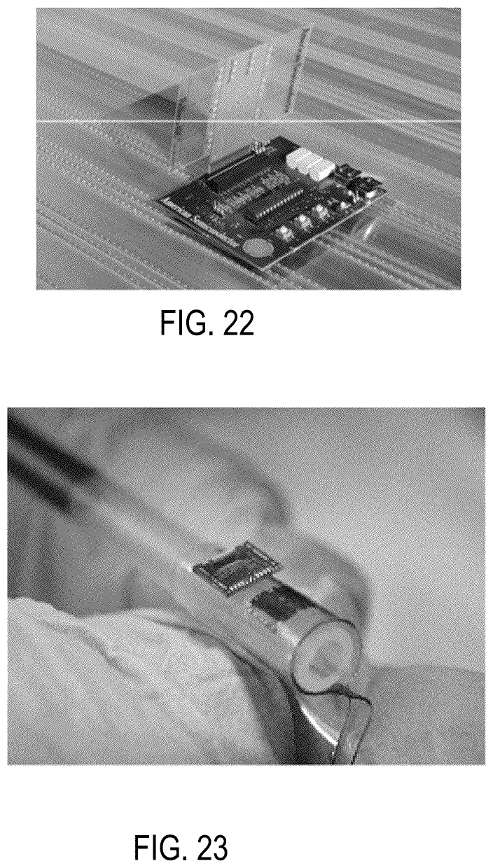

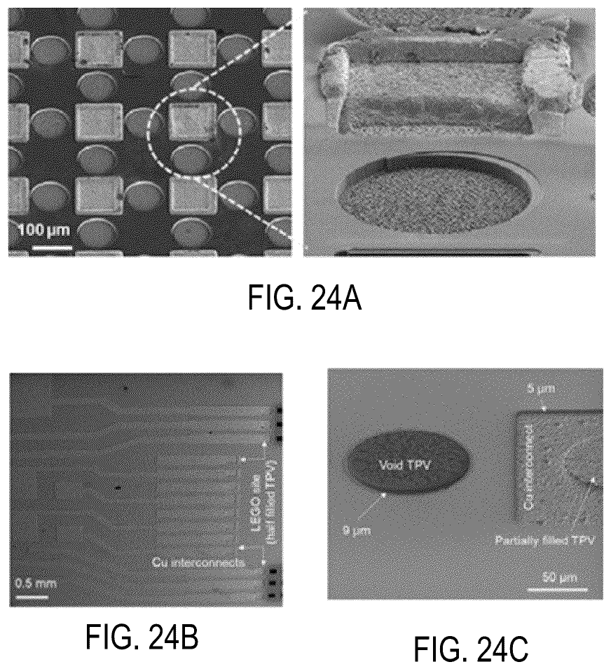

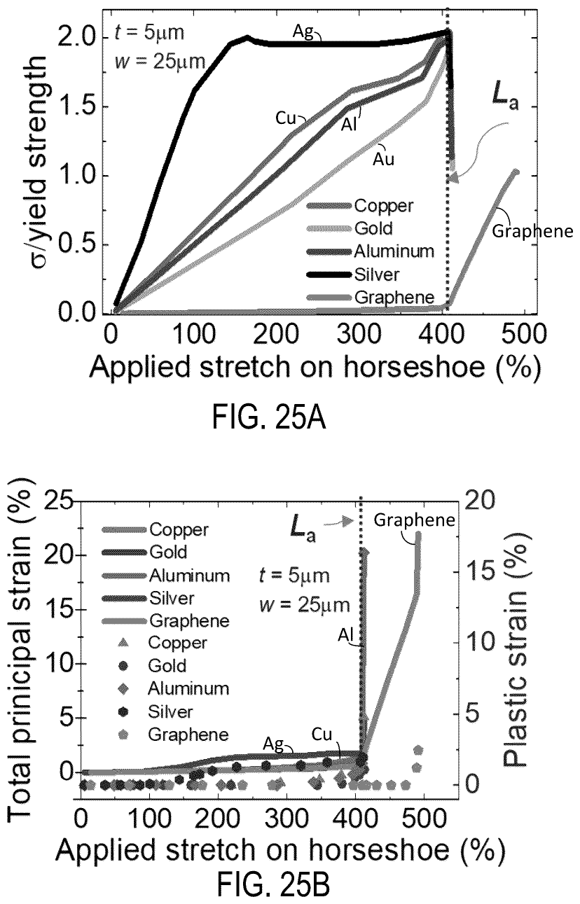

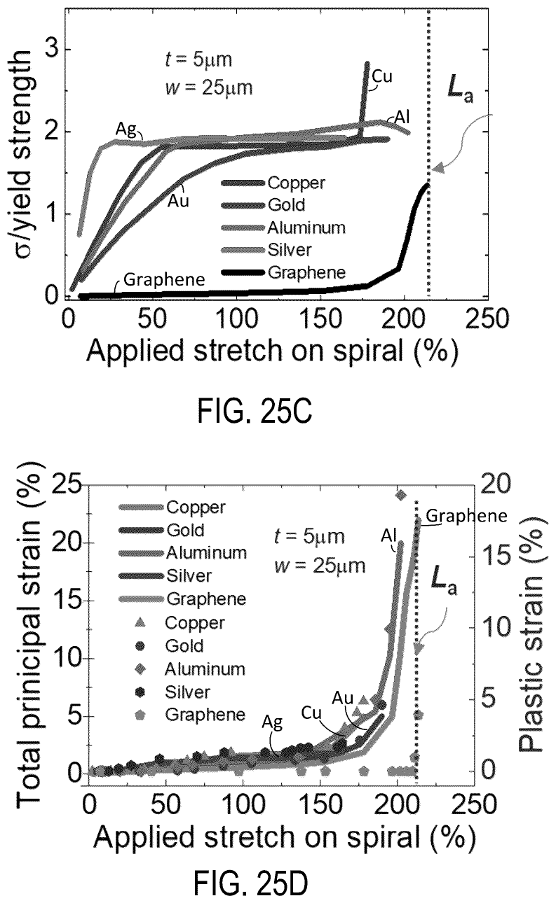

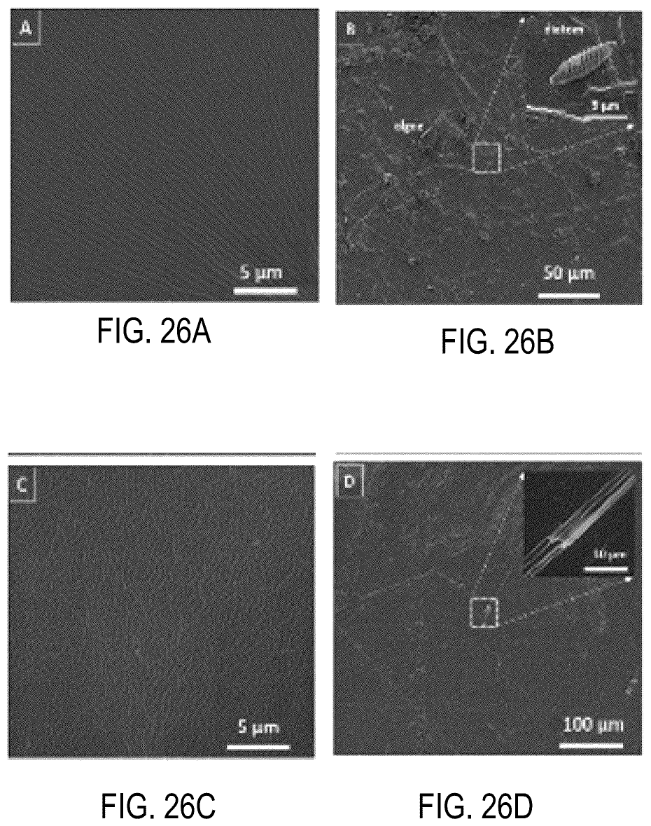

FIG. 18 illustrates an example of flexible hybrid electronics (e.g., the electronic assembly 105) with a fluidic assembly of chiplets (e.g., the electronic system 120). FIG. 19 illustrates an example of flexible hybrid electronics (e.g., the electronic assembly 105) with organic materials-based sensors (e.g., the sensor(s) 235). FIG. 20 illustrates an example of flexible chiplets. FIG. 21 illustrates an example flexible ADC development kit. FIG. 22 illustrates an example flexible BLE development kit. FIG. 23 illustrates an example flexible version of a microcontroller. FIGS. 24A-24C illustrates examples of through via formation and gap fill with interconnects. FIGS. 25A-24D are graphs illustrating a comparative study of modeling and experimental verification of a variety of stretchable interconnect materials. For instance, FIG. 25A is a graph illustrating a relationship between yield strength and applied stretch on a horseshoe. FIG. 25B is a graph illustrating a relationship between total principal strain and applied stretch on a horseshoe. FIG. 25C is a graph illustrating a relationship between yield strength and applied stretch on a spiral. FIG. 25D is a graph illustrating a relationship between total principal strain and applied stretch on a spiral. FIGS. 26A-26D illustrates a biofouling study on the encapsulated with a curated polymer.

The solution proposed by the technology disclosed herein overcomes a number of technical problems or challenges associated with, e.g., commercial availability of bare die chiplets, material supply and exploration, anomalous mechanical stress induced impact variability, biocompatibility, and manufacturing. As one example, the technology disclosed herein overcomes challenges associated with lack of chip layout. As another example, the technology disclosed herein allows for uniform growth of graphene, such as, e.g., via implementation of a more stable laser induced process. As another example, the technology disclosed herein may provide a library (or collection) of performance an reliability measurement, results, and design. As another example, the technology disclosed herein may allow for bio-compatibility of materials used for biofouling, prolonged deployment in fluidic environments with highly variable pH. As another example, to provide a lateral transfer to mainstream foundries, the technology disclosed herein may implement the disclosed integration strategy based on commercially available chiplets and SOTA CMOS processes.

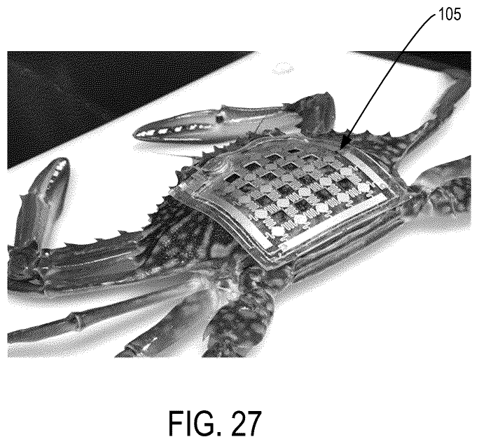

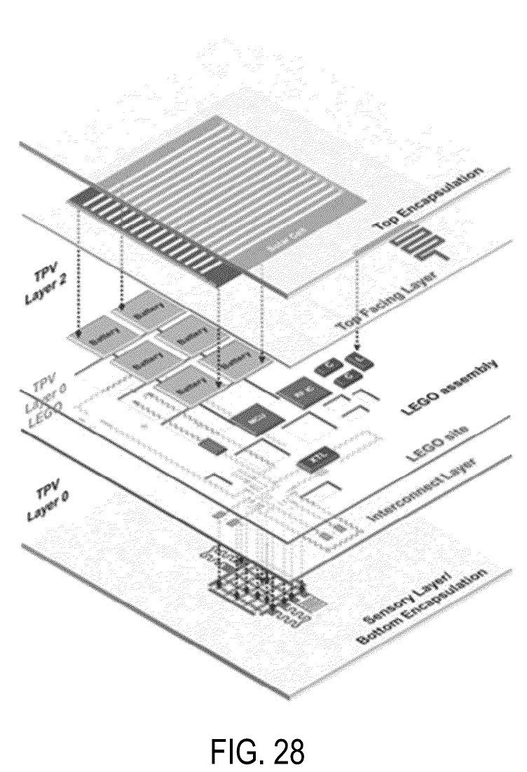

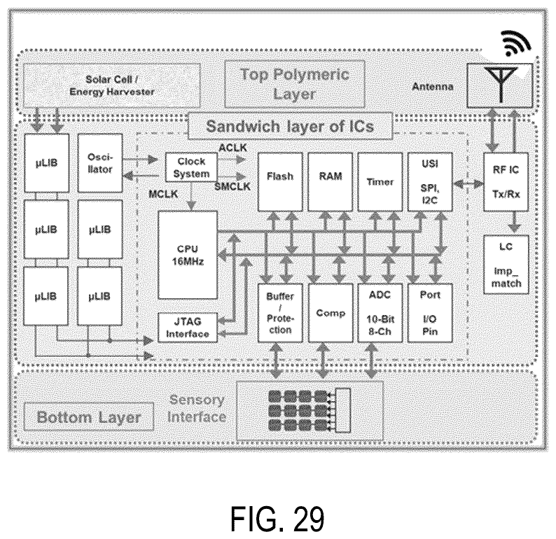

FIG. 27 illustrates the electronic assembly 105 implemented with respect to a crab to collect oceanic environmental data. In the example of FIG. 27, the electronic assembly 105 may be implemented as a common platform technology that is integrated with temperature, pressure, salinity, and pH sensors (e.g., the sensor(s) 425). As illustrated in FIG. 27, the electronic assembly 105 may be implemented with a cross bar matrix arrangement. In this example, the electronic assembly 105 may implement Bluetooth technology (e.g., via the communication interface 415) to transfer data (e.g., such as when the electronic assembly 105 is removed from the marine environment (e.g., the external environment 150)). Following this example, the technology disclosed herein may use functionalized and curated polymer technology as encapsulation materials (e.g., the encapsulation material 115). The implementation of FIG. 27 was deployed at a 2 km depth continuously for approximately 2 months without any degraded performance, which indicates success with respect to developing an advanced common platform technology specifically applicable for extreme environment applications. In some cases, the platform of the technology disclosed herein may be standalone and multisensory. In some configurations the components of the electronic assembly 105 may be physically compliant. The technology disclosed herein may be heterogeneously integrated using a 2.5/3D architecture, as illustrated in FIG. 28. FIG. 28 illustrates an example schematic of 2.5/3D flexible heterogeneously integrated system. Such an architecture may ensure faster data transportation, geometric area savings, large area for sensors and actuators, due to the non-proximity of the heat dissipating data integration electronic components it may reduce chance of inflammation. The platform of the technology disclosed herein may have microcontrollers with logic processing and memory storage capability (e.g., via the electronic processor(s) 400 and the memory 405), a power management circuitry (e.g., the power circuitry 420), a thin film micro lithium-ion battery array (e.g., included within the power circuitry 420) and Bluetooth technology based communication medium (e.g., via the communication interface 415). In some configurations, the sensor(s) 425, the actuator(s) 430, or a combination thereof may be on one end of the electronic assembly 105 while one or more antenna(s) (e.g., included as part of the communication interface 415) may be on an opposite end of the electronic assembly 105, as illustrated in FIG. 29. FIG. 29 provides a circuit block diagram of a common platform technology as described herein. In some instances, reducing the number of electronic components may be an effective strategy for flexible electronics.

Integrated circuits (IC) technology is the backbone of today's digital world. Over the decades, efforts have been made to make them faster, energy efficient and densely integrated. Billions of devices (e.g., transistors) have been fabricated on similar materials using monolithic integration. Silicon has served as the dominant material for logic and memory operation. Increased functionalities in our ICs is advantageous. One way to increase functionalities is to integrate ICs vertically in a 3D fashion resulting in a 3D-IC. This particular architecture may reduce interconnect delay, power consumption, and overall footprint. Nonetheless, the concept of heterogeneously integrated 3D-IC is still at its infancy. 3D-IC may allow stacking of dissimilar materials based ICs with varied functionalities into one single system.

Efforts toward 3D-IC are very limited. Some educational institutions are making efforts that focus on modeling and experimental work for thermal optimization, a variety of bonding techniques, and interconnects formation. Therefore, the technology disclosed herein may serve as a complementary effort to further strengthening the academic efforts toward 2.5/3D-IC, but in physically flexible form. The technology disclosed herein may allow more skilled workforce development (through involved students), new knowledge generation involving hybrid materials co-integration, etc.

Technological advances to augment quality of life involve Internet of Things (IoT) and Internet of Everything (IoE) seamlessly connecting device, data, people, and processes. A true IoT and then IoE system involves a pragmatic approach to integrate trillions of sensors on complex, asymmetrical and ever changing biological and non-living surfaces and workable under a variety of extreme environments.

Therefore, robust integration strategy is involved for a reliable physically compliant electronic system. There are plenty of efforts going on in the emerging field of flexible electronics, exploring OD/1D/2D materials, organic materials, polymers and low-cost processing techniques. Nonetheless, for data management they still need conventional rigid ICs. Therefore, different approaches have been explored to use self-assembled layers, thinned devices, microbumps as interlayer connector, specific bonding layer, and high temperature process requiring pressure application for stack bonding. Variety of methods are used to reduce the CMOS devices into a thin and flexible form. Simply stacking ICs without substantial thickness reduction and interconnecting using through-silicon-via (TSV) is not efficient area utilization and the stack itself becomes thick thereby losing the flexibility.

Therefore, today no clear strategies which are at the higher TRL is available. In the past mainstream semiconductor consortium has demonstrated ultra-thin-chip packaging in flexible encapsulation but no system level demonstration has been made for room temperature, let alone extreme environment. Entities have some commercially available chips on plastics but such chips are not tuned for extreme environment applications.

Some of the applications for the technology disclosed herein may include, e.g., health and environmental monitors, co-integrated sensors and actuators for artificial intelligence enabled unprecedented systems, which can not only sense and compute but also can execute an action using in-situ actuators (e.g., personalized medicinal platform), etc. Such personalized medicinal platform can be used for space and defense applications. To elaborate further, such an application may be an artificial intelligence enabled heterogeneously integrated platform that can automatically provide urgent medication to a user who is wounded or incapable to receive any medical attention in the battlefield or incapacitate to provide life-saving support. This autonomous platform may be wearable or contain multiple layers. The layer that may be in attachment with the skin may have multiple sensors and actuators. The next layer (away from the skin) may contain microfluidic assembly to store, mix or centrifuge, heat, measure and deliver transdermally through a needle (one of the mechanical actuators in the skin-contacted layer). The next layer may contain an electronics layer that may be assembled using 2.5/3D integration and the data integration chiplets and batteries (e.g., chip-scale) may be procured from commercially available ASIC bare die chips (chiplets) and interconnected via flexible and stretchable interconnects. The chiplets may be sufficiently thinned down to 20 mm thickness so the chiplets are physically conformal. The upper layer farthest from the skin may contain an antenna and solar cells to harvest energy. Every layer can be detached from each other for easy replacement. The sensors may be able to monitor body posture, temperature, heart rate, blood pressure, and moisture level while the actuators may be able to provide transfusion, compression, heat, and light therapy. Artificial intelligence may analyze the health condition and may decide and formulate the appropriate medication. The microfluidic layer may prepare the medication and may transfuse; other actuators may be actuated upon command from the AI unit. During the process, communication with the nearest soldiers and base may occur. Depending on the condition and availability, the whole procedure can be overridden by remotely located medics. This assembly may provide a personalized urgent medicinal platform (PUMP).

Common combat injuries include, e.g., second and third degree burns, broken bones, shrapnel wounds, brain injuries, spinal cord injuries, nerve damage, paralysis, loss of sight and hearing, post-traumatic stress disorder (PTSD), limb loss, etc. More than 70% of the near instant but preventable death happens from non-compressible torso hemorrhage where external pressure may not be sufficient. In some configurations, the technology disclosed herein may be implemented to provide immediate attention and care to, e.g., wounded soldiers.

Accordingly, the technology disclosed herein may be applicable within defense and space industries, automobile and automation sectors, petrochemical industries, etc.

Unless otherwise specified or limited, the terms “about” and “approximately,” as used herein with respect to a reference value, refer to variations from the reference value of ±20% or less (e.g., ±15, +10%, ±5%, etc.), inclusive of the endpoints of the range. Similarly, as used herein with respect to a reference value, the term “substantially equal” (and the like) refers to variations from the reference value of ±5% or less (e.g., ±2%, ±1%, ±0.5%) inclusive. Where specified in particular, “substantially” can indicate a variation in one numerical direction relative to a reference value. In particular, the term “substantially less” than a reference value (and the like) indicates a value that is reduced from the reference value by 30% or more (e.g., 35%, 40%, 50%, 65%, 80%), and the term “substantially more” than a reference value (and the like) indicates a value that is increased from the reference value by 30% or more (e.g., 35%, 40%, 50%, 65%, 80%).

Other examples and uses of the disclosed technology will be apparent to those having ordinary skill in the art upon consideration of the specification and practice of the technology disclosed herein. The specification and examples given should be considered exemplary only, and it is contemplated that the appended claims will cover any other such embodiments or modifications as fall within the true scope of the technology disclosed herein.

The Abstract accompanying this specification is provided to enable the United States Patent and Trademark Office and the public generally to determine quickly from a cursory inspection the nature and gist of the technical disclosure and in no way intended for defining, determining, or limiting the present technology disclosed herein or any of its embodiments.

What is claimed is:

1. A system, comprising:
an electronic system including at least one rigid electrical component, the electronic system configured to interact with an external environment, wherein the external environment has an environmental condition that satisfies an environment threshold, wherein the environment threshold indicates whether the external environment is an extreme environment; and
an encapsulation material configured to enclose the electronic system, wherein the encapsulation material has a plurality of material properties, the plurality of material properties including:
a first material property that defines a bending radius of the encapsulation material such that the encapsulation material has a degree of flexibility that corresponds to the bending radius; and
a second material property that establishes a compatibility of the encapsulation material with the external environment such that the encapsulation material prevents an adverse impact on the electronic system due to the external environment.

2. The system of claim 1, wherein the bending radius of the encapsulation material is substantially equal to 1 centimeter.

3. The system of claim 1, wherein the bending radius of the encapsulation material is substantially equal to 2 centimeters.

4. The system of claim 1, wherein the bending radius of the encapsulation material is greater than or equal to 1 centimeter and less than or equal to 2 centimeters.

5. The system of claim 1, wherein the encapsulation material is glass.

6. The system of claim 1, wherein the electronic system is configured to interact with the external environment by monitoring a parameter of the external environment using a sensor of the electronic system.

7. The system of claim 1, wherein the electronic system is configured to interact with the external environment by performing an action with respect to an element included in the external environment.

8. The system of claim 1, wherein the external environment includes at least one of:
a biological environment internal to a living or nonliving being;
an oceanic environment;
a geothermal environment;
an outer space environment;
an arctic environment; or
a tropical environment.

9. The system of claim 1, wherein the environment threshold defines an ambient temperature range that substantially includes −25 degrees Celsius as a first endpoint and 130 degrees Celsius as a second end point; and wherein the environmental condition is an ambient temperature that is within the ambient temperature range defined by the environment threshold.

10. The system of claim 1, wherein the environment threshold defines a pressure range that substantially includes 0 torr as a first endpoint and 45600 torr as a second endpoint; and wherein the environmental condition is a pressure that is within the pressure range defined by the environment threshold.

11. The system of claim 1, wherein the environment threshold defines a humidity range that substantially includes 20% as a first endpoint and 100% as a second endpoint; and wherein the environmental condition is a humidity that is within the humidity range defined by the environment threshold.

12. The system of claim 1, wherein the environment threshold defines a salinity range that substantially includes 9 parts per thousand (ppt) as a first endpoint and 36 ppt as a second endpoint; and wherein the environmental condition is a salinity level that is within the salinity range defined by the environment threshold.

13. The system of claim 1, wherein the environment threshold defines a pH range that substantially includes 1 as a first endpoint and 14 as a second endpoint; and wherein the environmental condition is a pH within the pH range defined by the environment threshold.

14. An assembly, comprising:
an electronic system including a plurality of electrical components, the electronic system to be implemented within an external environment having an environmental condition that satisfies an extreme environment threshold; and
an encapsulation material configured to enclose at least one electrical component of the plurality of electrical components, wherein the encapsulation material has a plurality of material properties, the plurality of material properties including:
a first material property that defines a bending radius of the encapsulation material such that the encapsulation material has a degree of flexibility that corresponds to the bending radius, wherein the bending radius is between approximately 1 centimeter and 2 centimeters; and
a second material property that establishes a compatibility of the encapsulation material with the external environment such that the encapsulation material prevents the environmental condition from having an adverse impact on the at least one electrical component of the electronic system.

15. The assembly of claim 14, wherein, when the at least one electrical component of the electronic system is exposed to the environmental condition of the external environment without being enclosed by the encapsulation material, the environmental condition has an adverse impact on the at least one electrical component.

16. The assembly of claim 14, wherein the encapsulation material is glass.

17. The assembly of claim 14, wherein each electrical component of the plurality of electrical components is rigid; and wherein the plurality of electrical components includes: a communication interface; an electronic processor; a power circuit; and at least one of a sensor or an actuator; and wherein the electronic processor is configured to control the at least one of the sensor or the actuator to interact with the external environment.

18. An apparatus, comprising:
an electronic system including a plurality of electrical components, wherein the electronic system to be implemented within an external environment, wherein the external environment has an environmental condition that satisfies an environment threshold that classifies the external environment as an extreme environment, wherein the environmental condition includes at least one of:
a temperature that is within a temperature range defined by the environment threshold, the temperature range being-25 degrees Celsius to 130 degrees Celsius;
a pressure that is within a pressure range defined by the environment threshold, the pressure range being 0 torr to 45600 torr;
a humidity that is within a humidity range defined by the environment threshold, the humidity range being 20% to 100%;
a salinity level that within of a salinity range defined by the environment threshold, the salinity range being 9 parts per thousand (ppt) to 36 ppt; or
a pH within a pH range defined by the environment threshold, the pH range being 1 to 14; and
an encapsulation material configured to enclose at least one electrical component of the plurality of electrical components, wherein the encapsulation material has a bending radius of approximately 1 centimeter and 2 centimeters, and wherein the encapsulation material has a material property that is tolerant to the environmental condition of the external environment such that the encapsulation material prevents the environmental condition from having an adverse impact on the at least one electrical component of the electronic system.

19. The apparatus of claim 18, wherein the encapsulation material is glass.

20. The apparatus of claim 18, wherein each electrical component of the plurality of electrical components is rigid and is electrically coupled to another electrical component of the plurality of electrical components; and wherein, when deployed within the external environment, the encapsulation material causes the apparatus to be flexible.
